(19) United States
(12) Patent Application Publication
(10) Pub. No.: US 2008/0110665 A1
(43) Pub. Date: May 15, 2008

(54) Method for Connecting Printed Circuit Board

(76) Inventors: Kazuo Satoh, Tokyo (JP); Hideo Yamazaki, Sagamihara (JP)

Correspondence Address: 3M INNOVATIVE PROPERTIES COMPANY, PO BOX 33427, ST. PAUL, MN, 55133-3427, US

(21) Appl. No.: 11/814,300

(22) PCT Filed: Jan. 24, 2006
(86) PCT No.: PCT/US06/02417

§ 371 Date: Jul. 19, 2007

(30) Foreign Application Priority Data
Feb. 3, 2005 (JP) 2005027636

(51) Int. Cl. H01R 12/04; C09J 163/00; H05K 1/09; H05K 1/02

(52) U.S. Cl. 174/254; 156/330

(57) ABSTRACT

To provide a PCB that does not generate a short-circuit problem even at a very small pitch and has high connection reliability a method is provided for connecting a printed circuit board (PCB) to a second circuit board comprising: providing a printed circuit board (PCB) having a connection portion; providing a second circuit board having a connection portion, the second circuit board to be connected to the PCB, wherein the connection portion of one or both of the PCB and second circuit board has at least one conductive bump, positioning the connection portion of the PCB opposite the connection portion of the second circuit board with a thermosetting adhesive film between the connection portions of the PCB and second circuit board, and applying heat and pressure to the connection portions and the thermosetting adhesive film such that the adhesive film is displaced sufficiently to allow electrical contact between the at least one bump and the connection portion of the opposing circuit board and such that the heat is sufficient to cause the adhesive to set. Also provided is an article comprising a PCB having a connection portion with at least one conductive bump, and a thermosetting adhesive film on the surface of the connection portion.

### TECHNICAL FIELD

This invention relates to a method for connecting a printed circuit board (PCB) to another circuit board (wiring board) or to an article that is used for the above method.

### BACKGROUND ART

Electronic appliances such as digital cameras, cellular telephones, printers, and so forth, use in many cases a printed circuit board including a flexible printed circuit board (FPC; hereinafter merely called “FPC”) bonded to other wiring board. These electronic appliances are rendered small in size, and connection of the FPC having wires of fine pitches to other wiring board has been more and more required.

When the FPC is connected to other wiring board, it has been customary in the past to employ a method that forms bumps on connection portions of the FPC, brings the bumps into contact with electrodes provided to other wiring board and solders them together to establish connection. However, pitches between the connection portions on the FPC become miniaturized, and as the pitches become smaller, a problem of short-circuit with the adjacent connection portions becomes more likely to occur. In addition, another problem exists in that physical strength of the solder connection portions of the fine pitches is low and connection stability is inferior. Therefore, development of a connection method of FPC with other wiring board that does not invite the problem of short-circuit but has high connection reliability has been required.

On the other hand, Patent Document 1 (Japanese Unexamined Patent Publication (Kokai) No. 2003-243447) discloses a packaging method of semiconductor chips that forms bumps on semiconductor chips and connects them to a wiring board through a thermosetting adhesive. In this case, the connection counterpart can be applied only to a wiring board having an electronic circuit including input and output portions having a size smaller than that of the semiconductor chip.

### BRIEF DESCRIPTION OF THE DRAWINGS

FIGS. 1(a) and 1(b) are sectional views of an FPC that can be used in the method of the invention.

FIGS. 2(a) and 2(b) are sectional views of another FPC that can be used in the method of the invention.

FIG. 3 is a process step view of a connection method of the invention.

FIGS. 4(a) to 4(d) are perspective views showing various bump shapes.

FIGS. 5(a) and 5(b) are schematic views of possible arrangement positions of the bumps.

FIGS. 6(a) and 6(b) are schematic views of connection patterns.

### DISCLOSURE

At least one aspect of the present invention provides a method for connecting a printed circuit board (PCB) such as FPC to another circuit board which method does not invite a problem of short-circuit even when pitches are small, and has high connection reliability in comparison with connection by soldering between PCB and other circuit board according to the prior art.

At least one aspect of the present invention provides a PCB equipped with a thermosetting adhesive film that can be used for the electrical connection method described above.

According to one aspect of the invention, there is provided a method for connecting a printed circuit board (PCB) to a second circuit board comprising:

providing a printed circuit board (PCB) having a connection portion;

providing a second circuit board having a connection portion, the second circuit board to be connected to the PCB,

wherein the connection portion of one or both of the PCB and second circuit board has at least one conductive bump,

positioning the connection portion of the PCB opposite the connection portion of the second circuit board with a thermosetting adhesive film between the connection portions of the PCB and second circuit board, and

applying heat and pressure to the connection portions and the thermosetting adhesive film such that the adhesive film is displaced sufficiently to allow electrical contact between the at least one bump and the connection portion of the opposing circuit board and such that the heat is sufficient to cause the adhesive to set.

According to another aspect of the invention, there is provided an article comprising a printed circuit board (PCB) having a connection portion with at least one conductive bump, and a thermosetting adhesive film on the surface of the connection portion.

The article, PCB equipped with the adhesive film can be used for the connection method of PCB and another circuit board that is described above.

Unlike the case of connection by soldering between the PCB equipped with bumps and another board according to the prior art, connection is established in the invention while the adhesive film is sandwiched between the connection portions, and the problem of short-circuit does not occur even when the pitches between the connection portions is small. Because the connection portions are supported and fixed by the adhesive film, connection is not released by external stress and connection reliability can be improved.

The invention will be explained using the following embodiments but is not particularly limited to the concrete embodiments described herein.

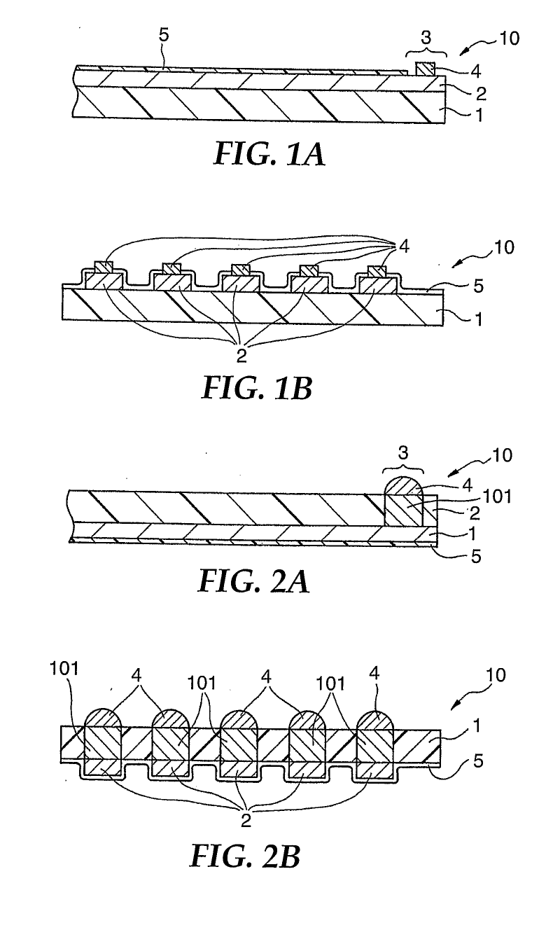

Although a printed circuit board (PCB) used in the present invention is not particularly limited, for example, it may be rigid or flexible, it is preferably a flexible printed circuit board (FPC), which is more difficult to be connected to another circuit board. The FPC may be of any type. A second circuit board to which the FPC may be attached is also not particularly limited. For example, it may be rigid or flexible. It is also possible that one of the FPC and second circuit board may be rigid while the other is flexible, or both may be flexible or rigid. When connection portions of a second circuit board have bumps, for example, an ordinary FPC can be used. When the connection portions on the FPC have the bumps, on the other hand, the following FPC can be used. The FPC may be a lead-type FPC 10 equipped with bumps 4 which FPC has wires 2 of copper, etc, on the surface of a resin film 1 and bumps on its connection portions 3 as shown in FIG. 1. The bumps may be any suitable shape. Generally, the FPC is coated with an insulating film 5 to secure an insulating property at portions other than the connection portions 3. Incidentally, FIG. 1(a) is a sectional view when the FPC is cut along the direction of the wires and FIG. 1(b) is a sectional view when the FPC is cut in such a fashion as to contain the connection portions in a direction orthogonally intersecting FIG. 1(a).

Alternatively, the FPC may be of a via-type FCP 10 having wires 2 of copper, etc, on the back side of a resin film 1 and equipped with bumps 4 on connection portions 3 as shown in FIG. 2. The connecting portions 3 are connected to wires 2 on the back side of the resin film 1 through vias 101. Generally, the FPC is covered with an insulating film 5 on portions other than the connection portion to secure the insulating property. FIG. 2(a) is a sectional view when the FPC is cut in the direction of the wires and FIG. 2(b) is a sectional view when the FPC is cut in a direction orthogonally intersecting FIG. 2(a) in such a manner as to include the connection portions.

The height of bump is preferably 5 μm to 100 μm for both types of FPC of FIGS. 1 and 2. If the height of bump 4 is too high, connection portion between FPCs becomes bulky and stable connection may not be established. If the height of bump is too low, electric contact effect by the bump is not sufficient. Here, the height of bump is the height from the surface of wiring line to the top of bump for FPC type shown in FIG. 1. For FPC type shown in FIG. 2, the height of bump is the height from the surface of FPC resin film (opposite to wiring line side) to the top of bump. The width of bump is preferably 15 to 200 μm, and the length of bump is preferably 30 to 500 μm.

The FPC equipped with bumps can be formed on the connection portions of ordinary FPC by various methods such as a printing method, an ink jet method, a plating method, and so forth. The material of the bumps may be a conductor such as solder (Sn—Ag—Cu, for example), copper, nickel and gold. To produce core bumps from the solder, the printing method and the ink jet method can be conveniently used. In the case of the metal such as copper, nickel or gold, the plating method can be used. The surface of the bumps may be finished by use of tin, gold, nickel or a nickel/gold alloy so that electric connection with the connection portions of other wiring board can be satisfactorily established. The bumps may be on one or both of the top surface and bottom surface of a circuit board.

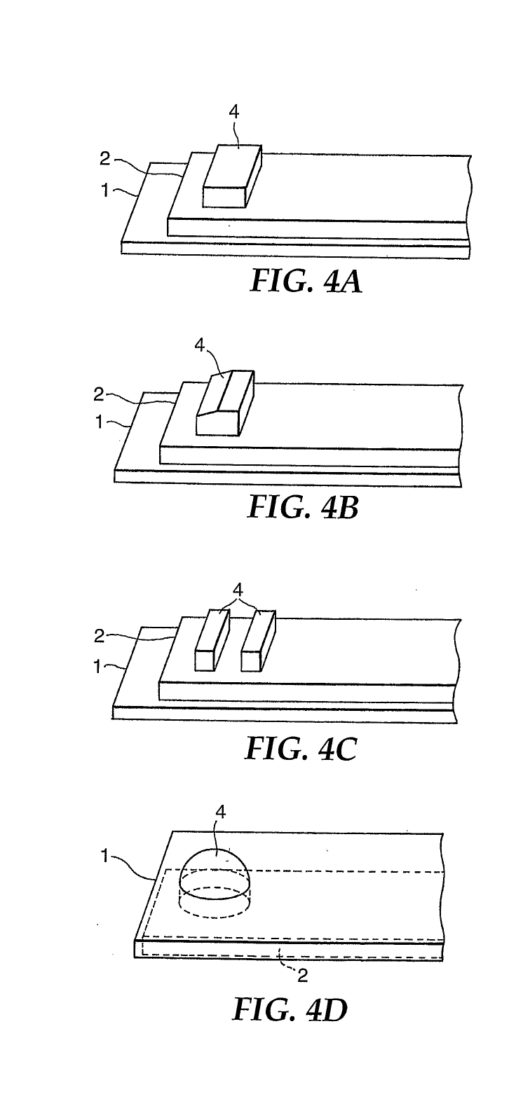

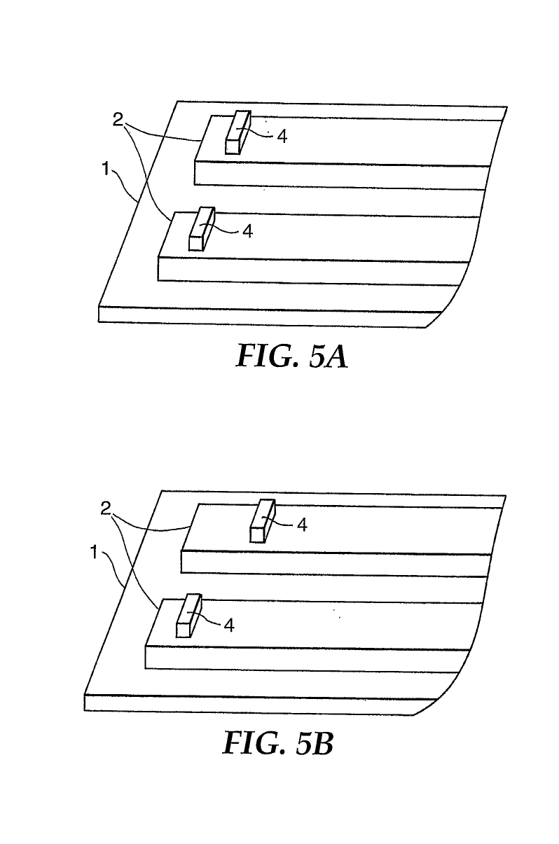

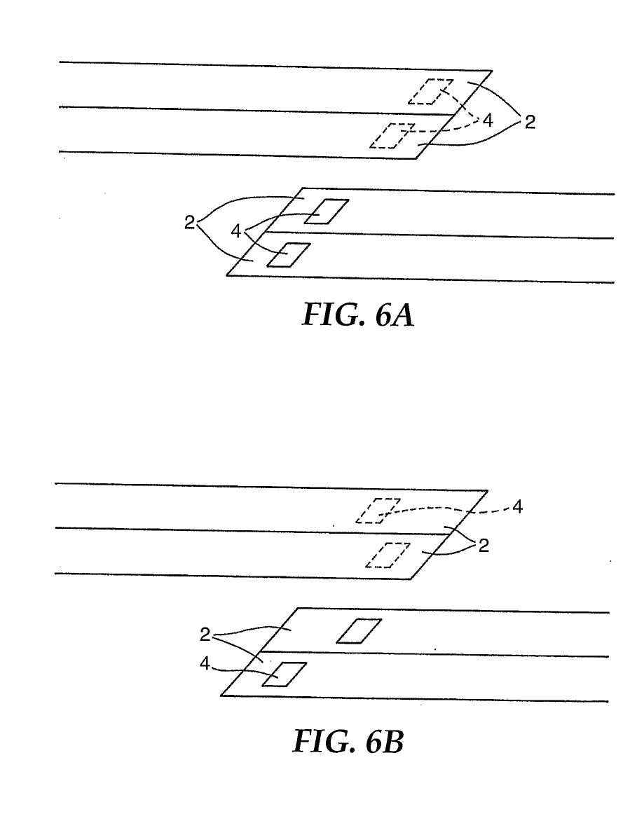

There may also be multiple conductive bumps on one or both surfaces of a circuit board. Multiple bumps may be located on a single wire or trace, for example as shown in FIG. 4(c) or may be located on adjacent wires or traces. The multiple conductive bumps may be in a row, for example as shown in FIGS. 5(a) and 6(a), or may be offset from each other, for example as shown in FIGS. 5(b) and 6(b).

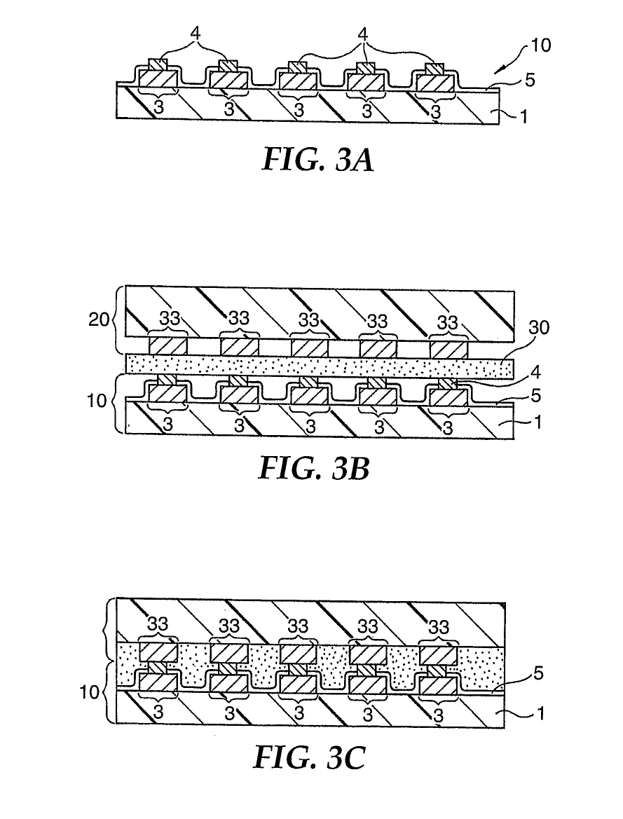

A connection method of the PCB according to the invention will be hereinafter explained stepwise, using FPC as PCB. FIG. 3 is a process diagram of the connection method according to the invention. Incidentally, the bumps may be formed on either one of the side of the FPC and the second wiring board or on both of them. In the following explanation, however, a flexible printed circuit board (FPC) has the bumps formed on the surface of the connection portions and the bumps are not formed on the connection portions of the second wiring board. First of all, a flexible printed circuit board (FPC) 10 having bumps 4 formed of a conductor on the surface of the connection portions is prepared (Step (a)). Next, a second wiring board 20 to be connected to this FPC 10 is prepared and positioning is made between the connection portions 3 of the FPC 10 and the connection portions 33 of the second wiring board 20. The FPC 10 and the second wiring board 20 are put one upon another through a thermosetting adhesive film 30 (Step (b)). A stacked body of the FPC 10, the thermosetting adhesive film 30 and the wiring board 20 is heat pressed to establish electric connection between the connection portions of the FPC 10 and the connection portions of the second wiring board 20 (Step (c)).

Incidentally, an FPC equipped with an adhesive film may be acquired by preparing a flexible printed circuit board (FPC) 10 having bumps formed of a conductor on the surface of connection portions and heat pressing in advance a thermosetting adhesive film 30 on the surface. The surface of the adhesive film of the FPC equipped with the adhesive film may be thereafter superposed with the second wiring board 20.

Heat pressing is made through compressing by use of a heated flat plate. The temperature and the pressure for heat pressing are decided in accordance with a resin composition of the adhesive film selected and are not limited. Generally, it is preferred to use an adhesive film containing a resin component having a fluidization temperature of 60 to 170° C. and a setting temperature of 170 to 260° C. in the invention. In heat pressing for obtaining the FPC equipped with an adhesive film, a heating temperature of about 150 to 230° C., a heating time of 1 to 10 seconds and a pressure of 5 to 200 N/cm² are suitably used. Consequently, the adhesive film is allowed to fluidize and to adhere to the FPC but is not completely set and keeps its thermosetting property. In heat pressing at the time of connection with the second wiring board, a temperature of not lower than 200° C., a heating time of 1 to several minutes and a pressure of 5 to 200 N/cm² are used suitably.

Incidentally, the term “fluidization temperature” means a temperature at which the viscosity of a polymer resin is 10,000 Pa·s or below and can be measured by use of a plastometer or a viscoelastometer. The term “setting temperature” means a temperature at which the setting reaction of the thermosetting polymer proceeds at least 50% in the course of 60 minutes and can be measured by the viscoelastometer or a differential scanning calorimeter (DSC). The detail of the thermosetting composition that can be used for the adhesive film will be described later.

The second wiring board to which the PCB such as FPC is connected in the method of the invention may be a wiring board of any type. For example, the second wiring board may be a rigid wiring board such as a glass epoxy substrate. Alternatively, the second wiring board may be a flexible wiring board such as an FPC.

In the invention, electric connection becomes possible as the bumps formed on the connection portions displace the adhesive fluidized at the time of thermal pressing and come into satisfactory contact with the connection portions of the wiring board. Therefore, the formation of the bumps is important. FIGS. 4(a) to 4(d) are perspective views showing various bump forms. In FIGS. 4(a) to 4(c), bumps 4 having various shapes are formed on the wires 2 of the resin film 1. In FIG. 4(d), the wire 2 exists on the back of the resin film 1, a via-hole connects the back to the surface of the resin film 1 and the bump 4 is formed there. Various bump shapes are possible besides the shapes shown in the drawing, and the bump shape is not particularly limited so long as they are suitable for electric connection in the method of the invention.

FIGS. 5(a) and 5(b) are schematic views of possible arrangement positions of the bumps. The bumps may be arranged at the same positions with respect to the corresponding connection portions as shown in FIG. 5(a) or at alternate positions as shown in FIG. 5(b). When the second wiring board, which may also have bumps, is combined with the FPC under the arrangement condition shown in FIG. 5(a), connection is made under the state schematically shown in FIG. 6(a). In this case, since the bumps are formed on both boards and contact the connection portion of the opposing board at two different positions, connection stability of the connection portion can be improved. On the other hand, when the second wiring board is combined with the FPC under the arrangement condition shown in FIG. 5(b), connection is made under the state schematically shown in FIG. 6(b).

Next, Table 1 tabulates suitable forms of the formation method of the core bumps when the bumps are formed on the FPC, the material of the core bumps, surface finish of the core bumps and the material of the connection portions of the second wiring board.

TABLE 1
Table 1: Combination of connection portion

| | | | surface | |
|---|---|---|---|---|
| | core bump | | finish | |
| | formation | | on core | connection portion of |
| | method | core bump | bump | second wiring board |
| 1) | printing method | solder | Nil | solder, Au Ni/Au, Cu, |
| | ink jet method | (Sn—Ag—Cu) | | Ag—Pd |
| | | (Sn—Pb) | | |
| 2) | plating method | copper | Sn | solder, Au Ni/Au |
| 3) | plating method | copper | Ni/Au | solder, Au Ni/Au, Al |
| | | | Au | |
| 4) | plating method | Ni | Sn | solder, Au Ni/Au |
| 5) | plating method | Ni | Au | solder, Au Ni/Au, Al |
| 6) | plating method | Au | Nil | solder, Au Ni/Au, Al |

Among the combinations described above, 2) is ordinarily used.

In at least one embodiment of the present invention, after attachment of the PCB and second circuit board, the connected PCB and second circuit board may be reheated to soften the adhesive sufficiently to allow the PCB and second circuit board to be separated. Subsequently, the PCB and second circuit board may be reattached by positioning the connection portion of the PCB opposite the connection portion of the second circuit board with the thermosetting adhesive between the connection portions of the PCB and second circuit board, then heat and pressure may be applied to the connection portions and the thermosetting adhesive such that the adhesive film is displaced sufficiently to allow electrical contact between at least one bump, on the PCB or on the connection portion of the second circuit board, and the connection portion of the opposing circuit board and wherein the heat is sufficient to cause the adhesive to re-set.

In another embodiment of the present invention, a second connection portion of the PCB may be positioned opposite a connection portion of a third circuit board with a second thermosetting adhesive film between the second connection portions of the PCB and the connection portion of the third circuit board, then heat and pressure may be applied to the second connection portion of PCB and connection portion of the third circuit board and the thermosetting adhesive film such that the adhesive film is displaced sufficiently to allow electrical contact between at least one bump, on the PCB or on the connection portion of the third circuit board, and the connection portion of the opposing circuit board and wherein the heat is sufficient to cause the adhesive to set.

Next, the adhesive film used in the invention will be described. The invention uses an adhesive film (hereinafter called “thermosetting adhesive film” or “adhesive film”) containing a thermo-fluidizable, thermosetting resin (hereinafter called “thermosetting resin”) that exhibits fluidity when heated to a certain temperature and is set when it is further heated. The thermo-fluidizable, thermosetting resin comprises both thermosetting component and thermoplastic component. In the first embodiment, the thermo-fluidizable, thermosetting resin can be a mixture of a thermoplastic resin such as a phenoxy resin and a thermosetting resin such as an epoxy resin. In the second embodiment, the thermo-fluidizable, thermosetting resin can be a thermosetting resin that is modified by a thermoplastic component. An example of the second embodiment is a polycaprolactone-modified epoxy resin. In the third embodiment, the thermo-fluidizable, thermosetting resin can be a copolymer resin having a thermosetting group such as an epoxy group in the basic structure of the thermoplastic resin. An example of such a copolymer resin is a copolymer between ethylene and glycidyl (meth)acrylate.

The adhesive composition that can be used particularly suitably for the adhesive film is a thermosetting adhesive composition containing the caprolactone-modified epoxy resin.

Such a thermosetting adhesion composition generally has a crystalline phase. In at least one embodiment, the crystalline phase contains the caprolactone-modified epoxy resin (hereinafter called also “modified epoxy resin”) as its main component. The modified epoxy resin applies suitable flexibility to the thermosetting adhesive composition and can improve viscoelastic properties of the thermosetting adhesive. As a result, the thermosetting adhesive has aggregation force before setting and exhibits higher bonding power upon heating. The modified epoxy resin becomes a set product having a three-dimensional network structure by heating in the same way as an ordinary epoxy resin and can apply the aggregation force to the thermosetting adhesive.

From the aspect of the improvement of initial bonding power, the modified epoxy resin generally has an epoxy equivalent of about 100 to about 9,000, suitably about 200 to about 5,000 and more suitably about 500 to about 3,000. An example of a suitable modified epoxy resin having such an epoxy equivalent is commercially available from Dicel Kagaku Kogyo K. K. under the trade name PLACELL G series.

The thermosetting adhesive composition preferably contains a melamine/isocyanuric acid adduct (hereinafter called “melamine/isocyanuric acid complex”) in combination with the modified epoxy resin described above. A useful melamine/isocyanuric acid complex is commercially available from Nissan Kagaku Kogyo K. K. under the trade name MC-600, for example, and is effective for increasing toughness of the thermosetting adhesive composition, for reducing tack of the thermosetting adhesive composition before setting by the exhibition of thixotropic property and for suppressing hygroscopicity and fluidity of the thermosetting adhesive composition. To prevent brittleness after setting without spoiling the effects described above, the thermosetting adhesive composition can contain generally 1 to 200 parts by weight, preferably 2 to 100 parts by weight and more preferably 3 to 50 parts by weight, of this melamine/isocyanuric acid complex on the basis of 100 parts by weight of the modified epoxy resin.

The thermosetting adhesive composition can be cured such that it has sufficient strength to connect the PCBs in normal use but it can be softened when further heated. This is possible since the thermosetting adhesive can be cured with controlled manner.

When a caprolactone-modified epoxy resin is used for a thermo-fluidizable, thermosetting resin, the thermosetting adhesive composition can further contain a thermoplastic resin to improve repair property. The term “repair property” means the capacity such that the adhesive film can be peeled by heating after the connection step is carried out and connection can be again made. The thermosetting adhesive is reworkable, wherein “reworkable” means that after the adhesive is initially set, it can be softened or melted and, optionally, re-set.

A phenoxy resin is a thermoplastic resin having a chain-like or linear structure and a relatively high molecular weight and formed from epichlorohydrin and bis-phenol A. Such a phenoxy resin has high processability and the thermosetting adhesive composition can be easily processed into the adhesive film. According to one embodiment of the invention, this phenoxy resin is contained in the thermosetting adhesive composition generally in an amount of 10 to 300 parts by weight and preferably 20 to 200 parts by weight on the basis of 100 parts by weight of the modified epoxy resin. The phenoxy resin is effectively compatible with the modified epoxy resin. Therefore, phase separation between the modified epoxy resin and the phenoxy resin, and thus bleeding of the modified epoxy resin from the thermosetting resin can effectively be prevented. The phenoxy resin entangles with the set product of the modified epoxy resin and further improves final aggregation force and heat resistance of the thermosetting adhesive layer. Furthermore, the repair property after connection can be secured.

Whenever necessary, the thermosetting adhesive composition may further contain a second epoxy resin (hereinafter merely called “epoxy resin”) in combination with, or independently of, the phenoxy resin described above. This epoxy resin is not particularly limited so long as it is not out of the scope of the invention. It is possible to use, for example, a bis-phenol A type epoxy resin, a bis-phenol F type epoxy resin, a bis-phenol A glycidyl ether type epoxy resin, a phenol novolak type epoxy resin, a cresol novolak type epoxy resin, a fluorine epoxy resin, a glycidylamine resin, an aliphatic epoxy resin, a brominated epoxy resin, a fluorinated epoxy resin, and so forth. Such epoxy resins are compatible with the phenoxy resin in the same way as the modified epoxy resin and their bleeding from the thermosetting adhesive composition hardly occurs. The heat resistance can be advantageously improved particularly when the thermosetting adhesive composition contains suitably 50 to 200 parts by weight and more suitably 60 to 140 parts by weight of the second epoxy resin on the basis of 100 parts by weight of the modified epoxy resin.

In an embodiment of the invention, a bis-phenol A diglycidyl ether type epoxy resin (hereinafter called “diglycidyl ether type epoxy resin”) can be used as the preferred epoxy resin. This diglycidyl ether type epoxy resin is liquid and can improve high temperature characteristics of the thermosetting adhesive composition, for example. When this diglycidyl ether type epoxy resin is used, chemical resistance due to setting at a high temperature and a glass transition temperature, for example, can be improved. It will make it possible to use a various curing agents and setting process will be relatively mild. Such a diglycidyl ether type epoxy resin is commercially available from Dow Chemical (Japan) Co. under the trade name D.E.R. 332.

A curing agent can be added, whenever necessary, to the thermosetting adhesive composition and can be used for the setting reaction of the epoxy resin of the above thermosetting resin and the second epoxy resin. The amount of use of this curing agent and its kind are not particularly limited so long as the curing agent provides the desired effect. From the aspect of the improvement of the heat resistance, however, the thermosetting adhesive composition contains generally 1 to 50 parts by weight, preferably 2 to 40 parts by weight and more preferably 5 to 30 parts by weight of the curing agent on the basis of 100 parts by weight of the epoxy resin and the optional second epoxy resin. Examples of the curing agent, though not restrictive, include an amine curing agent, an acid anhydride, dicyandiamide, a cationic polymerization catalyst, an imidazole compound, a hydrazine compound, and so forth. Dicyandiamide, in particular, can be cited as a promising curing agent because it has thermal stability at room temperature. In connection with the diglycidyl ether type epoxy resin, alicyclic polyamine, polyamide, amide amine and their modified products are preferably used.

In the thermosetting adhesive composition, 15 to 100 parts by weight of organic particles can be added to 100 parts by weight of the adhesive composition described above. When the organic particles are added, the resin comes to exhibit plastic fluidity while restricts excessive fluidity of the thermosetting adhesive composition and prevents the adhesive from flowing out during heat pressing in the bonding step of the adhesive film to the connector and in the connection step with the wiring board. Moisture adhering to the wiring board is likely to evaporate and a vapor pressure is likely to operate during heating in the connection step with the wiring board and in such a case, too, the resin fluidizes and can entrap bubbles.

The organic particles added are those of an acrylic resin, a styrene-butadiene resin, a styrene-butadiene-acryl resin, a melamine resin, a melamine-isocyanurate adduct, polyimide, a silicone resin, polyether imide, polyether sulfone, polyester, polycarbonate, polyether ether ketone, polybenzoimidazole, polyarrylate, a liquid crystal polymer, an olefin resin and an ethylene-acrylic copolymer. The particle size is 10 μm or below and preferably 5 μm or below.

### EXAMPLES

### Example 1

An FPC equipped with a bump structure that has a construction shown in FIG. 1 is prepared. More concretely, the FPC has a construction in which each copper bump 4 is formed by plating on a connection portion 3 (land) at the distal end of a wire 2 (thickness: 15 μm, width 36 μm) formed of a copper lead on a resin film 1 (25 μm thick) formed of polyimide, and the surface of the bump is plated with gold (Au). The bump 4 has a width of 36 μm, a length of 60 μm, and a height of 15 μm.

The same FPC as described above with the exception that the bump is not formed is used as the second wiring board to which the FPC is to be connected.

The adhesive film is obtained by forming a liquid composition tabulated in Table 2, coating the liquid composition on a polyethylene terephthalate (PET) film the PET film having been release treated with silicone and drying the film at 100° C. for 30 minutes to a thickness of 25 μm.

The adhesive film is put on the FPC equipped with the bump described above and after positioning of the connection portions is made, another FPC as the second wiring board is superposed and is heat pressed by using a heat bonder at a temperature of 200° C. and at a pressure of 100 N/cm² for 1 minutes.

Satisfactory mutual connection of the resulting FPC is confirmed by a milli-ohm meter.

TABLE 2
Adhesive Composition

| trade designation | material | Parts by weight |
|---|---|---|
| YP50S | phenoxy resin | 30 |
| DER332 | epoxy resin | 34 |
| G-402 | polycaprolactone-modified epoxy | 30 |
| EXL-2314 | acrylic polymer | 80 |
| DICY | dicyandiamide | 2.9 |
| MeOH | methanol | 40 |
| THF | tetrahydrofuran | 550 |
| MC600 | melamine-isocyanuruic acid complex | 20 |

NOTE)
Phenoxy resin: YP50S, product of Toto Kasei K. K., number average molecular weight: 11,800
Epoxy resin: DER332, product of Dow Chemical (Japan) Co., epoxy equivalent: 174 Polycaprolactone-modified epoxy: G402, product of Dicell Kagaku Kogyo K. K. (epoxy equivalent: 1,350)
Acrylic polymer particle: EXL2324, Kureha Pararoid EXL, Kureha Chemical Industry Co., Ltd.
DICY: dicyandiamide CG-NA, product of PTI Japan K. K.
Melamine isocyanuric acid complex: MC-600, Nissan Kagaku Kogyo, K. K.

1. A method for connecting a printed circuit board to a second circuit board comprising:
providing a printed circuit board having a connection portion;
providing a second circuit board having a connection portion, the second circuit board to be connected to the printed circuit board,
wherein the connection portion of one or both of the printed circuit board and second circuit board has at least one conductive bump,
positioning the connection portion of the printed circuit board opposite the connection portion of the second circuit board with a thermosetting adhesive film between the connection portions of the printed circuit board and second circuit board, and
applying heat and pressure to the connection portions and the thermosetting adhesive film such that the adhesive film is displaced sufficiently to allow electrical contact between the at least one bump and the connection portion of the opposing circuit board and such that the heat is sufficient to cause the adhesive to set.

2. A method of claim 1 wherein the thermosetting adhesive film contains a thermoplastic component and a thermosetting component.

3. A method of claim 2 wherein the thermosetting adhesive film contains a caprolactone-modified epoxy resin.

4. A method of claim 1 further comprising reheating the connected printed circuit board and second circuit board to soften the adhesive sufficiently to allow the printed circuit board and second circuit board to be separated.

5. A method of claim 4 further comprising
reattaching the printed circuit board and second circuit board by positioning the connection portion of the printed circuit board opposite the connection portion of the second circuit board with the thermosetting adhesive between the connection portions of the printed circuit board and second circuit board, and
applying heat and pressure to the connection portions and the thermosetting adhesive such that the adhesive film is displaced sufficiently to allow electrical contact between the at least one bump and the connection portion of the opposing circuit board and such that the heat is sufficient to cause the adhesive to re-set.

6. A method of claim 4 further comprising positioning the printed circuit board to a third circuit board by positioning a second connection portion of the printed circuit board opposite a connection portion of the third circuit board with a second thermosetting adhesive film between the second connection portions of the printed circuit board and connection portion of the third circuit board, and
applying heat and pressure to the second connection portion of printed circuit board and connection portion of the third circuit board and the thermosetting adhesive film such that the adhesive film is displaced sufficiently to allow electrical contact between the at least one bump and the connection portion of the opposing circuit board and such that the heat is sufficient to cause the adhesive to set.

7. An article comprising a printed circuit board having a connection portion with at least one conductive bump, and a thermosetting adhesive film on the surface of the connection portion.

8. An article of claim 7 wherein the printed circuit board is flexible.

9. An article of claim 7 wherein the connection portion of the printed circuit board is attached to a connection portion of a second circuit board by the thermosetting adhesive film such that the at least one conductive bump on the connection portion of the printed circuit board is in electrical contact with the connection portion of the second circuit board.

10. An article of claim 9 wherein the connection portion of the second circuit board further comprises at least one conductive bump in electrical contact with the conductive portion of the printed circuit board.

11. An article of claim 7 wherein the printed circuit board is rigid.

12. An article of claim 9 wherein one of the printed circuit board and the second circuit board is flexible and one is rigid.

13. An article of claim 7 wherein the bump is made of a material selected from the group of solder, copper, nickel, and gold.

14. An article of claim 7 wherein the printed circuit board has at least one conductive bump on a top surface and at least one conductive bump on a bottom surface.

15. An article of claim 7 wherein the printed circuit board has multiple conductive bumps.

16. An article of claim 15 wherein the multiple conductive bumps are in a row.

17. An article of claim 15 wherein at least one of the multiple conductive bumps is offset from at least one other bump.

18. An article of claim 7 wherein the thermosetting adhesive film contains a thermoplastic component and a thermosetting component.

19. An article of claim 7 wherein the thermosetting adhesive is reworkable.
